(19) United States
(12) Patent Application Publication
(10) Pub. No.: US 2020/0266130 A1
(43) Pub. Date: Aug. 20, 2020

(54) SEMICONDUCTOR DEVICE

(71) Applicant: TOYOTA JIDOSHA KABUSHIKI KAISHA, Toyota-shi (JP)

(72) Inventor: Takanori KAWASHIMA, Anjo-shi (JP)

(73) Assignee: TOYOTA JIDOSHA KABUSHIKI KAISHA, Toyota-shi (JP)

(21) Appl. No.: 16/745,779

(22) Filed: Jan. 17, 2020

(30) Foreign Application Priority Data
Feb. 20, 2019 (JP) 2019-028856

(51) Int. Cl. H01L 23/492; H01L 23/498

(52) U.S. Cl. CPC H01L 23/492; H01L 23/49838

(57) ABSTRACT

A semiconductor device disclosed herein may include: a semiconductor element including a signal pad; and a signal terminal including a flat surface opposed to the signal pad, the flat surface being bonded to the signal pad with a spacer interposed therebetween. The flat surface may be larger than the signal pad in at least one direction parallel to the flat surface.

### CROSS-REFERENCE TO RELATED APPLICATION

This application claims priority to Japanese Patent Application No. 2019-028856, filed on Feb. 20, 2019, contents of which are incorporated herein by reference.

### TECHNICAL FIELD

The technology disclosed herein relates to a semiconductor device.

### BACKGROUND

Japanese Patent Application Publication No. 2004-296588 describes a semiconductor device. This semiconductor device is provided with a semiconductor element, a signal terminal electrically connected to a signal pad, and a heat dissipating member including a conductor layer bonded to the semiconductor element. The signal terminal is electrically connected to the signal pad of the semiconductor element by being bonded to the conductor layer via a solder layer.

### SUMMARY

In the semiconductor device described above, one end of the signal terminal is connected to the signal pad of the semiconductor element via the conductor layer. In regard to this, the one end of the signal terminal may be directly bonded to the signal pad of the semiconductor element to reduce a size of the semiconductor device. However, since a size of the signal pad is relatively small, there is a possibility that a bonding material, such as solder, could contact a portion of the semiconductor element other than the signal pad due to an unintended positional displacement of the signal terminal. The disclosure herein provides a technology that can solve or at least mitigate such a problem.

A semiconductor device disclosed herein may comprise a semiconductor element comprising a signal pad and a signal terminal comprising a flat surface opposed to the signal pad. The flat surface may be bonded to the signal pad with a spacer interposed therebetween. The flat surface may be larger than the signal pad in at least one direction parallel to the flat surface.

### BRIEF DESCRIPTION OF DRAWINGS

FIG. 1 is a plan view of a semiconductor device 10 of a first embodiment.

FIG. 2 is a plan view of an internal structure of the semiconductor device 10, with an encapsulant 30 illustrated by a broken line to clarify depiction of the internal structure.

FIG. 3 is a cross-sectional view along a line of FIG. 1, and shows the internal structure of the semiconductor device 10.

FIG. 4 is an enlarged view of a portion IV of FIG. 3, where depiction of the encapsulant 30 is omitted to clarify depiction of the internal structure of the semiconductor device 10.

FIG. 5 is an enlarged view of a portion V of FIG. 2, and is a diagram explaining a size relationship between a signal pad 20d and a first signal terminal 14.

FIG. 6 is a diagram explaining a first reflow process.

FIG. 7 is a diagram explaining a second reflow process.

FIG. 8 is a diagram showing a variant of the signal pad 20d.

FIG. 9 is a diagram showing a variant of the first signal terminal 14 and a signal terminal spacer 12.

FIG. 10 is a diagram showing another variant of the first signal terminal 14 and the signal terminal spacer 12.

FIG. 11 is a diagram showing yet another variant of the first signal terminal 14 and the signal terminal spacer 12.

FIG. 12 is a cross-sectional view of a semiconductor device 100 of a second embodiment, and shows an internal structure thereof.

### DETAILED DESCRIPTION

In an embodiment of the technology disclosed herein, a semiconductor device may comprise a semiconductor element comprising a signal pad and a signal terminal comprising a flat surface opposed to the signal pad. The flat surface may be bonded to the signal pad with a spacer interposed therebetween. The flat surface may be larger than the signal pad in at least one direction parallel to the flat surface.

The signal terminal of the above-described semiconductor device includes the flat surface opposed to the signal pad. The flat surface is larger than the signal pad in at least one direction parallel to the flat surface. According to this configuration, even when the signal terminal is positionally displaced in the at least one direction, the flat surface of the signal terminal can remain opposed to an entirety or a substantially entirety of the signal pad. Since a bonding material (such as solder) that bonds the flat surface and the signal pad is retained on the signal pad regardless of a position of the signal terminal, the bonding material is suppressed from contacting an unintended portion of the semiconductor element. Further, since the spacer is arranged between the flat surface of the signal terminal and the signal pad, a certain distance can be provided between the flat surface of the signal terminal and the signal pad. Thus, direct contact of the flat surface with a portion of the semiconductor element other than the signal pad can also be avoided.

In an embodiment of the technology disclosed herein, the signal pad may be larger than the spacer in the at least one direction. According to this configuration, a bonding material that bonds the signal pad and the spacer can be shaped in a fillet shape, by which the signal pad and the spacer can firmly be bonded together.

In an embodiment of the technology disclosed herein, an end portion of the signal terminal may extend along a first direction and the end portion may include at least the flat surface. In this case, the at least one direction may comprise the first direction.

In addition to the above, the at least one direction may further comprise a second direction perpendicular to the first direction. According to this configuration, regardless of whether the signal terminal is positionally displaced in the first direction or in the second direction, the flat surface of the signal terminal can remain opposed to the entirety or substantially entirety of the signal pad. Since the bonding material that bonds the flat surface and the signal pad is retained on the signal pad regardless of a position of the signal terminal, the bonding material is suppressed from contacting an unintended portion of the semiconductor element.

In an embodiment of the technology disclosed herein, the spacer may have a pillar shape including one end surface opposed to the flat surface and another end surface opposed to the signal pad. According to this configuration, even when the signal terminal is positionally displaced, the one end surface of the spacer and the flat surface can at least remain opposed to each other, and the other end surface of the spacer and the signal pad can at least remain opposed to each other. Due to this, the bonding material that bonds the spacer, the signal terminal and the signal pad is suppressed from directly contacting an unintended portion of the semiconductor element. The pillar shape herein may include a cylindrical shape or a prism shape.

In an embodiment of the technology disclosed herein, the spacer may have a spherical shape. According to this configuration, an orientation of the spacer does not need to be controlled in manufacturing of the semiconductor device.

In an embodiment of the technology disclosed herein, the spacer may comprise a bottom surface opposed to the signal pad and may have a shape in which a cross sectional area of the spacer decreases continuously or stepwise toward the flat surface. According to this configuration, the orientation of the spacer relative to the signal pad is easily stabilized in manufacturing of the semiconductor device.

In an embodiment of the technology disclosed herein, the flat surface may be bonded to the signal pad via solder. In this case, the spacer may be located within the solder.

In an embodiment of the technology disclosed herein, at least a part of the signal terminal may be provided on an insulator substrate.

Representative, non-limiting examples of the present disclosure will now be described in further detail with reference to the attached drawings. This detailed description is merely intended to teach a person of skill in the art further details for practicing aspects of the present teachings and is not intended to limit the scope of the present disclosure. Furthermore, each of the additional features and teachings disclosed below may be utilized separately or in conjunction with other features and teachings to provide improved semiconductor devices, as well as methods for using and manufacturing the same.

Moreover, combinations of features and steps disclosed in the following detailed description may not be necessary to practice the present disclosure in the broadest sense, and are instead taught merely to particularly describe representative examples of the present disclosure.

Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### EMBODIMENTS

### First Embodiment

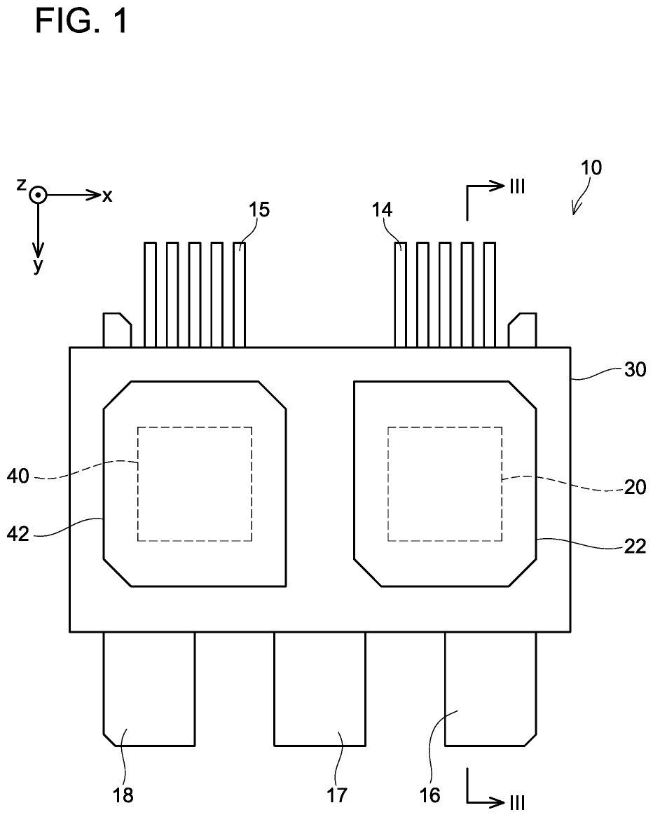

A semiconductor device 10 of a first embodiment and a method of manufacturing the same will be described with reference to FIGS. 1 to 7. The semiconductor device 10 is employed in a power controller and may configure a part of a power conversion circuit such as an inverter or a converter. The power controller herein is mounted, for example, on an electric vehicle, a hybrid vehicle, or a fuel cell vehicle.

As shown in FIG. 1, the semiconductor device 10 includes a first semiconductor element 20, a second semiconductor element 40, a plurality of external connection terminals 14, 15, 16, 17, 18, and an encapsulant 30. The first semiconductor element 20 and the second semiconductor element 40 are encapsulated within the encapsulant 30. The encapsulant 30 is constituted mainly of a material having insulation property. The encapsulant 30 may be constituted mainly of a thermosetting resin such as epoxy resin, although this is merely an example.

The plurality of external connection terminals 14, 15, 16, 17, 18 extends outward to protrude from the encapsulant 30. Each of the external connection terminals 14, 15, 16, 17, 18 is electrically connected to the first semiconductor element 20 or the second semiconductor element 40 inside the encapsulant 30. The plurality of external connection terminals 14, 15, 16, 17, 18 is constituted mainly of a conductor material such as copper. The plurality of external connection terminals 14, 15, 16, 17, 18 includes a plurality of first signal terminals 14, a plurality of second signal terminals 15, a first power terminal 16, a second power terminal 17, and a third power terminal 18. The plurality of first signal terminals 14 is electrically connected to the first semiconductor element 20, and the plurality of second signal terminals 15 is electrically connected to the second semiconductor element 40.

The first semiconductor element 20 is a power semiconductor element and is a switching element such as a MOSFET (Metal-Oxide-Semiconductor Field-Effect Transistor) or an IGBT (Insulated Gate Bipolar Transistor). The first semiconductor element 20 includes a semiconductor substrate 20a, a pair of main electrodes 20b, 20c, and signal pads 20d connected to the first signal terminals 14. The pair of main electrodes 20b, 20c includes a first main electrode 20b and a second main electrode 20c. The first main electrode 20b and the signal pads 20d are located on one surface of the semiconductor substrate 20a, and a size of each signal pad 20d is smaller than a size of the first main electrode 20b. On the other hand, the second main electrode 20c is located on another surface of the semiconductor substrate 20a. As a material constituting the semiconductor substrate 20a, silicon (Si), silicon carbide (SiC), gallium nitride (GaN), or other types of semiconductor materials may be used, for example. The pair of main electrodes 20b, 20c and the signal pads 20d are constituted mainly of a conductor material such as aluminum or other metal. The first main electrode 20b and the second main electrode 20c herein mean electrodes that are electrically connected to each other via the semiconductor substrate 20a.

The second semiconductor element 40 is a power semiconductor element and is a switching element such as a MOSFET (Metal-Oxide-Semiconductor Field-Effect Transistor) or an IGBT (Insulated Gate Bipolar Transistor). The second semiconductor element 40 includes a semiconductor substrate, a pair of main electrodes 40b, and signal pads 40d connected to the second signal terminals 15. The pair of main electrodes 40b includes a first main electrode 40b and a second main electrode. The first main electrode 40b and the signal pads 40d are located on one surface of the semiconductor substrate, and a size of each signal pad 40d is smaller than a size of the first main electrode 40b. On the other hand, the second main electrode is located on another surface of the semiconductor substrate. As a material constituting the semiconductor substrate, silicon (Si), silicon carbide (SiC), gallium nitride (GaN), or other types of semiconductor materials may be used, for example. The pair of main electrodes 40b and the signal pads 40d are constituted mainly of a conductor material such as aluminum or other metal. Semiconductor elements having the same configuration may be employed as the first semiconductor element 20 and the second semiconductor element 40, although not particularly limited so.

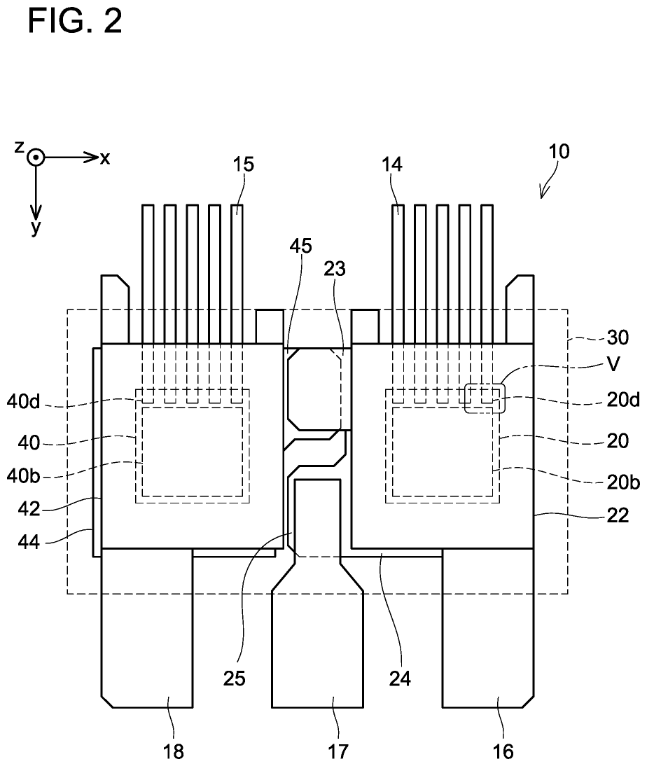

As shown in FIG. 2, the semiconductor device 10 is provided with a first lower heat dissipating plate 24 and a first upper heat dissipating plate 22 as well as a second lower heat dissipating plate 44 and a second upper heat dissipating plate 42. The first lower heat dissipating plate 24 and the first upper heat dissipating plate 22 are opposed to each other with the first semiconductor element 20 interposed therebetween. Further, the first lower heat dissipating plate 24 and the first upper heat dissipating plate 22 are electrically connected to the first semiconductor element 20. Similarly, the second lower heat dissipating plate 44 and the second upper heat dissipating plate 42 are opposed to each other with the second semiconductor element 40 interposed therebetween. Further, the second lower heat dissipating plate 44 and the second upper heat dissipating plate 42 are electrically connected to the second semiconductor element 40. The heat dissipating plates 22, 24, 42, 44 are members that have a substantially rectangular solid shape and are constituted mainly of a conductor material such as copper or other metal.

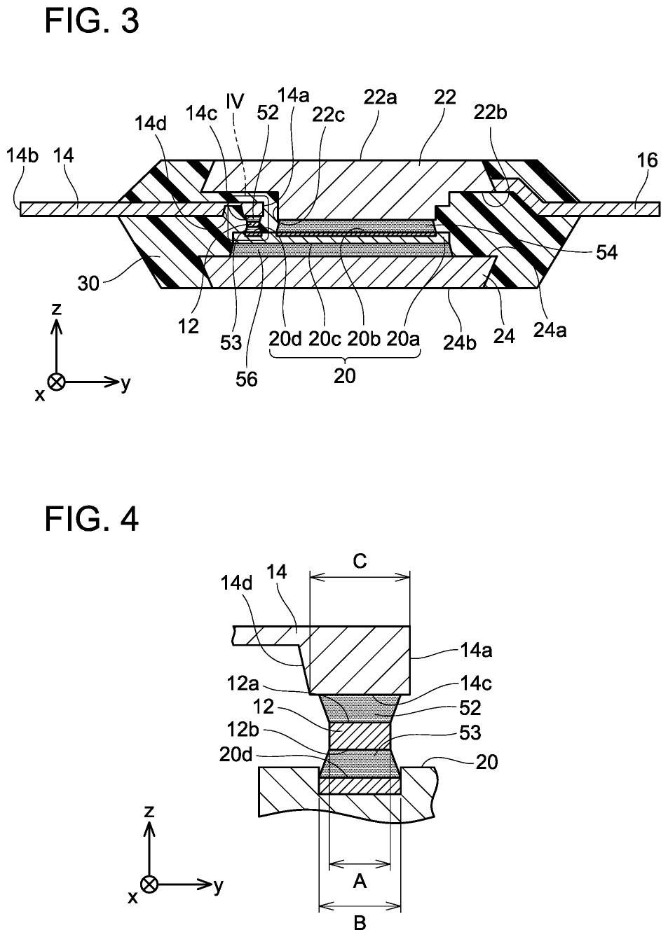

As shown in FIG. 3, the first lower heat dissipating plate 24 includes a first main surface 24a and a second main surface 24b located opposite to the first main surface 24a. The first main surface 24a of the first lower heat dissipating plate 24 is bonded to the second main electrode 20c of the first semiconductor element 20 via a solder layer 56. As such, the first lower heat dissipating plate 24 is electrically connected to the first semiconductor element 20. The second main surface 24b of the first lower heat dissipating plate 24 is exposed at one surface of the encapsulant 30.

Similarly, the first upper heat dissipating plate 22 includes a first main surface 22a and a second main surface 22b located opposite to the first main surface 22a. The first upper heat dissipating plate 22 is provided with a spacer portion 22c protruding from the second main surface 22b. In this regard, it differs from the first lower heat dissipating plate 24. The spacer portion 22c of the second main surface 22b of the first upper heat dissipating plate 22 is bonded to the first main electrode 20b of the first semiconductor element 20 via a solder layer 54. As such, the first upper heat dissipating plate 22 is electrically connected to the first semiconductor element 20. The first main surface 22a of the first upper heat dissipating plate 22 is exposed at another surface of the encapsulant 30. As such, the first lower heat dissipating plate 24 and the first upper heat dissipating plate 22 function also as heat dissipating plates that dissipate heat generated in the first semiconductor element 20.

The configuration of the first upper heat dissipating plate 22 is not limited to the above-described configuration. For example, instead of the spacer portion 22c of the first upper heat dissipating plate 22, a conductor spacer, which is a separated component, may be disposed between the first upper heat dissipating plate 22 and the semiconductor element 20. With this configuration, a space for bonding the first signal terminals 14 to the signal pads 20d can be secured as needed. The respective constituent members are bonded to each other by using a bonding material having conductivity, such as solder. However, the respective constituent members may not be soldered to each other, and may be bonded by other aspects. The second lower heat dissipating plate 44 and the second upper heat dissipating plate 42 have similar configurations to the first lower heat dissipating plate 24 and the first upper heat dissipating plate 22 respectively, thus descriptions for them will be omitted.

The first upper heat dissipating plate 22 is provided with a joint portion 23, and the second lower heat dissipating plate 44 is provided with a joint portion 45. The joint portion 23 of the first upper heat dissipating plate 22 and the joint portion 45 of the second lower heat dissipating plate 44 are electrically connected to each other. These two joint portions 23, 45 are soldered to each other, although this is merely an example. Further, the first lower heat dissipating plate 24 is provided with a joint portion 25. The joint portion 25 of the first lower heat dissipating plate 24 is electrically connected to the second power terminal 17. The joint portion 25 of the first lower heat dissipating plate 24 and the second power terminal 17 are soldered to each other, although this is merely an example. However, the two joint portions 23, 45 as well as the joint portion 25 and the second power terminal 17 are not limited to being bonded by soldering, and they may be bonded by other aspects having conductivity. Here, the first upper heat dissipating plate 22 and the joint portion 23 are configured integrally. However, a separate joint portion member may be connected to the first upper heat dissipating plate 22. In this case, the joint portion member may be bonded to the first upper heat dissipating plate 22 by welding, for example. The first lower heat dissipating plate 24 and the second lower heat dissipating plate 44 may be configured integrally with the joint portions 25, 45, or may be connected to separate joint portions, similar to the first upper heat dissipating plate 22.

Further, the first power terminal 16 is connected to the first upper heat dissipating plate 22. Similarly, the third power terminal 18 is connected to the second upper heat dissipating plate 42. The first power terminal 16 is bonded to the first upper heat dissipating plate 22 by welding, for example, and the third power terminal 18 is bonded to the second upper heat dissipating plate 42 by welding, for example. However, these connections are not limited to be realized by welding, and may be realized by other aspects.

A relationship between the first signal terminals 14 and the signal pads 20d will be described with reference to FIGS. 3 to 5. Each of the first signal terminals 14 is a substantially elongated plate-shaped member and extends from one end portion 14a thereof toward another end portion 14b thereof. Each of the first signal terminals 14 is electrically connected to corresponding one of the signal pads 20d. The first signal terminals 14 and the signal pads 20d are bonded together by using a bonding material having conductivity, such as solder, although this is merely an example.

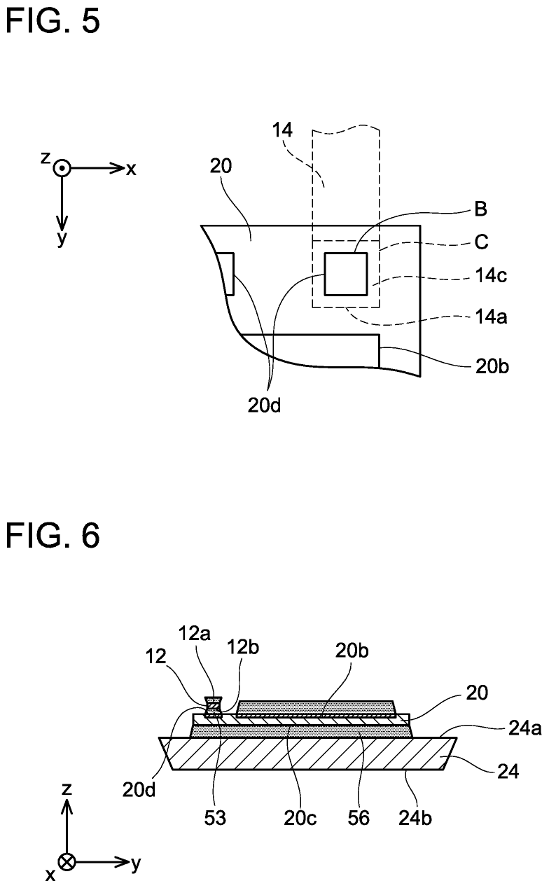

As shown in FIG. 4, each first signal terminal 14 includes a flat surface 14c on a one end portion 14a side, and the flat surface 14c is opposed to its corresponding signal pad 20d. Further, as shown in FIG. 5, a size (C) of the flat surface 14c is larger than a size (B) of the signal pad 20d in both X and Y directions. Further, the one end portion 14a including the flat surface 14c extends along the Y direction.

In addition, the semiconductor device 10 includes a plurality of signal terminal spacers 12. The signal terminal spacers 12 each have a substantially pillar shape and include a first end surface 12a and a second end surface 12b located opposite thereto. The signal terminal spacers 12 are constituted mainly of a conductor material such as metal. Each of the signal terminal spacers 12 is located between the flat surface 14c of each first signal terminal 14 and its corresponding signal pad 20d. As such, the flat surfaces 14c of the first signal terminals 14 are bonded to the signal pads 20d with the signal terminal spacers 12 interposed in between. In this configuration, the first end surfaces 12a of the signal terminal spacers 12 are opposed to the flat surfaces 14c, and the second end surfaces 12b of the signal terminal spacers 12 are opposed to the signal pads 20d. Due to this, the flat surfaces 14c of the first signal terminals 14 are bonded to the first end surfaces 12a of the signal terminal spacers 12 via solder layers 52, and the second end surfaces 12b of the signal terminal spacers 12 are bonded to the signal pads 20d via solder layers 53. Here, soldering is an example of bonding of a flat surface of a signal terminal to a signal pad with a spacer interposed therebetween in the art disclosed herein. The signal terminal spacers 12 are an example of the spacer in the art disclosed herein. The Y direction and the X direction are respectively examples of a first direction and a second direction in the art disclosed herein.

Here, the size (B) of the signal pads 20d is larger than a size (A) of the signal terminal spacers 12 in both the X and Y directions. As such, in the X and Y directions, the size (C) of the flat surfaces 14c of the first signal terminals 14 are larger than the size (B) of the signal pads 20d, and the size (B) of the signal pads 20d is larger than the size (A) of the signal terminal spacers 12 (see FIG. 4). This size relationship may be satisfied only in one of the X and Y directions.

Each of the first signal terminals 14 is provided with a recessed portion 14d adjacent to the flat surface 14c, although this is merely an example. The presence of the recessed portions 14d widens a spatial distance between the first signal terminals 14 and the first semiconductor element 20. Due to this, insulation between the first signal terminals 14 and unintended portions of the first semiconductor element 20 can be improved.

As described above, the size of the signal pads 20d is relatively small. Due to this, when the first signal terminals 14 are bonded to the signal pads 20d, unintended positional displacement of the first signal terminals 14 may possibly cause the bonding material, such as solder, to contact portions of the first semiconductor element 20 other than the signal pads 20d.

In regard to the above, as shown in FIG. 3, the first signal terminals 14 of the semiconductor device 10 of the present embodiment include the flat surfaces 14c opposed to the signal pads 20d. The flat surfaces 14c are larger than the signal pads 20d in at least one direction parallel to the flat surfaces 14c (in the X direction and/or the Y direction). According to this configuration, even when the first signal terminals 14 are positionally displaced in the at least one direction, the flat surfaces 14c of the first signal terminals 14 can remain opposed to entireties or substantially entireties of the corresponding signal pads 20d. Since the solder which bonds the flat surfaces 14c and the signal pads 20d is retained on the signal pads 20d regardless of positions of the first signal terminals 14, the solder is suppressed from contacting the unintended portions of the first semiconductor element 20. Further, since the signal terminal spacers 12 are arranged between the flat surfaces 14c of the first signal terminals 14 and the signal pads 20d, a certain distance can be ensured between the flat surfaces 14c of the first signal terminals 14 and the signal pads 20d. Thus, direct contact of the flat surfaces 14c to portions of the first semiconductor element 20 other than the signal pads 20d can be also avoided. Due to this, manufacturing quality of the semiconductor device 10 is improved.

Especially, in the semiconductor device 10 of the present embodiment, the size (C) of the flat surfaces 14c of the first signal terminals 14 is larger than the size (B) of the signal pads 20d in the X and Y directions. According to this configuration, regardless of in which direction among the Y and X directions the first signal terminals 14 are positionally displaced, the flat surfaces 14c of the first signal terminals 14 can remain opposed to the entireties or substantially entireties of the signal pads 20d. Since the solder bonding the flat surfaces 14c and the signal pads 20d is retained on the signal pads 20d regardless of the positions of the first signal terminals 14, the solder is suppressed from contacting the unintended portions of the first semiconductor element 20. Since the second signal terminals 15 have configurations similar to those of the first signal terminals 14, description for them will be omitted.

In the semiconductor device 10 of the present embodiment, each of the signal terminal spacers 12 has the pillar shape including the first end surface 12a opposed to the flat surface 14c and the second end surface 12b opposed to the signal pad 20d. According to this configuration, even when the first signal terminals 14 are positionally displaced, the first end surfaces 12a of the signal terminal spacers 12 and the flat surfaces 14c can at least remain opposed to each other, and the second end surfaces 12b of the signal terminal spacers 12 and the signal pads 20d can at least remain opposed to each other. Due to this, the solder bonding these elements is suppressed from directly contacting the unintended portions of the first semiconductor element 20.

In the semiconductor device 10 of the present embodiment, the signal pads 20d are larger than the signal terminal spacers 12 in the X direction and in the Y direction. According to this configuration, the solder bonding the signal pads 20d and the signal terminal spacers 12 can have a stable fillet shape, by which the signal pads 20d and the signal terminal spacers 12 are firmly bonded together.

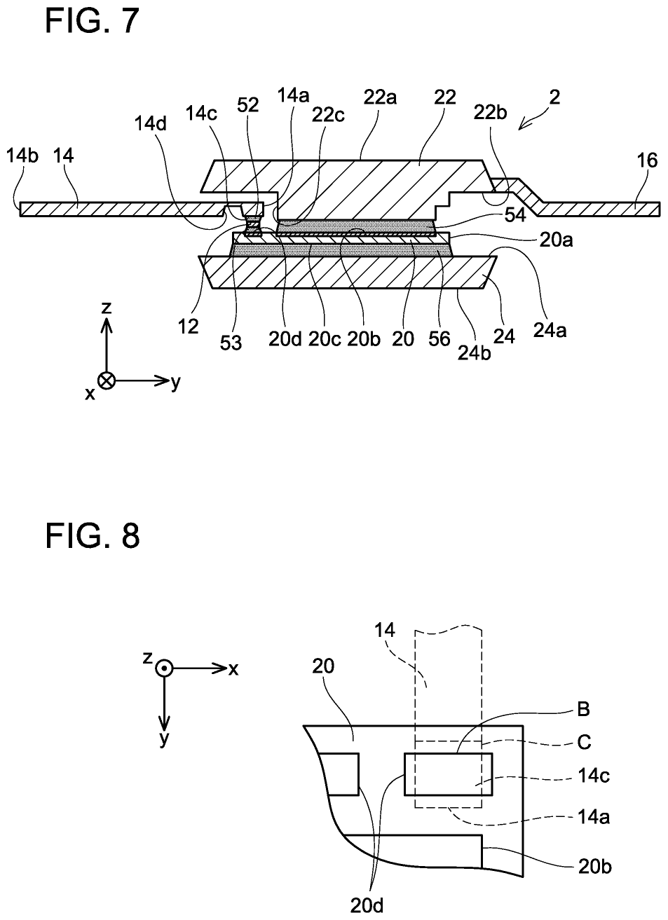

A manufacturing method of the semiconductor device 10 will be described with reference to FIGS. 6 and 7. The manufacturing method described hereinbelow relates to an assembly process of the semiconductor device 10, and especially relates to a first reflow process and a second reflow process for soldering the constituent members of the semiconductor device 10. Here, a lead frame 2, which is a component where the above-described plurality of first signal terminals 14, plurality of second signal terminals 15, first power terminal 16, second power terminal 17, third power terminal 18, first upper heat dissipating plate 22, and second upper heat dissipating plate 42 are integrally formed, is prepared and soldering is carried out thereto. However, this manufacturing method is merely an example, and no particular limitations are made thereto.

As shown in FIG. 6, the first reflow process is carried out. Firstly, the first semiconductor element 20, the first lower heat dissipating plate 24, and the plurality of signal terminal spacers 12 are prepared. At this occasion, the second semiconductor element 40 and the second lower heat dissipating plate 44 are also prepared. Hereinbelow, description will be made only for the first semiconductor element 20 as a representative example, however, the similar work is carried out on the second semiconductor element 40 as well. Then, the second main electrode 20c of the first semiconductor element 20 is arranged at its corresponding position on the first lower heat dissipating plate 24, and the signal terminal spacers 12 are arranged on the signal pads 20d of the first semiconductor element 20. Here, solder is interposed between the first lower heat dissipating plate 24 and the second main electrode 20c of the first semiconductor element 20 and between the signal pads 20d and the signal terminal spacers 12. This solder material may be solder in a sheet shape, although this is merely an example. After the arrangement, they are heated in a reflow furnace and are thereby soldered to each other. Due to this, the first lower heat dissipating plate 24 and the second main electrode 20c of the first semiconductor element 20 are bonded via the solder layer 56, and the signal pads 20d and the second end surfaces 12b of the signal terminal spacers 12 are bonded via the solder layers 53. In the first reflow process, preparatory solder may be arranged on the first main electrode 20b of the first semiconductor element 20 and on the first end surfaces 12a of the signal terminal spacers 12 as well, and may be melted and soldered concurrently with the above.

As shown in FIG. 7, the second reflow process is carried out. Firstly, the aforementioned lead frame 2 is prepared. Then, the lead frame 2 is arranged with high accuracy such that the second main surface 22b of the first upper heat dissipating plate 22 is arranged above the first main electrode 20b of the first semiconductor element 20 and the flat surfaces 14c of the first signal terminals 14 are arranged above the first end surfaces 12a of the signal terminal spacers 12. Here, solder is interposed between the first main electrode 20b of the first semiconductor element 20 and the second main surface 22b of the first upper heat dissipating plate 22 and between the first end surfaces 12a of the signal terminal spacers 12 and the flat surfaces 14c of the first signal terminals 14. This solder material may be solder in a sheet shape, although this is merely an example. After the arrangement, they are heated in the reflow furnace and are thereby soldered to each other. Due to this, the first main electrode 20b of the first semiconductor element 20 and the first upper heat dissipating plate 22 are bonded via the solder layer 54, and the first end surfaces 12a of the signal terminal spacers 12 and the flat surfaces 14c of the first signal terminals 14 are bonded via the solder layers 52.

The soldering of the semiconductor device 10 is completed by the above. Even when the first signal terminals 14 are positionally displaced in the at least one direction in the above-described manufacturing method, the flat surfaces 14c of the first signal terminals 14 can remain opposed to the entireties or substantially entireties of the signal pads 20d. Since the solder bonding the flat surfaces 14c and the signal pads 20d is retained on the signal pads 20d regardless of the positions of the first signal terminals 14, the solder is suppressed from contacting the unintended portions of the first semiconductor element 20. The arrangements of the respective constituent members in the first reflow process and in the second reflow process can be achieved with high accuracy by using a jig, for example.

The first signal terminals 14, the signal pads 20d, and the signal terminal spacers 12 are not limited to having the above-described configurations, and may have various configurations. Such variants will be described with reference to FIGS. 8 to 11.

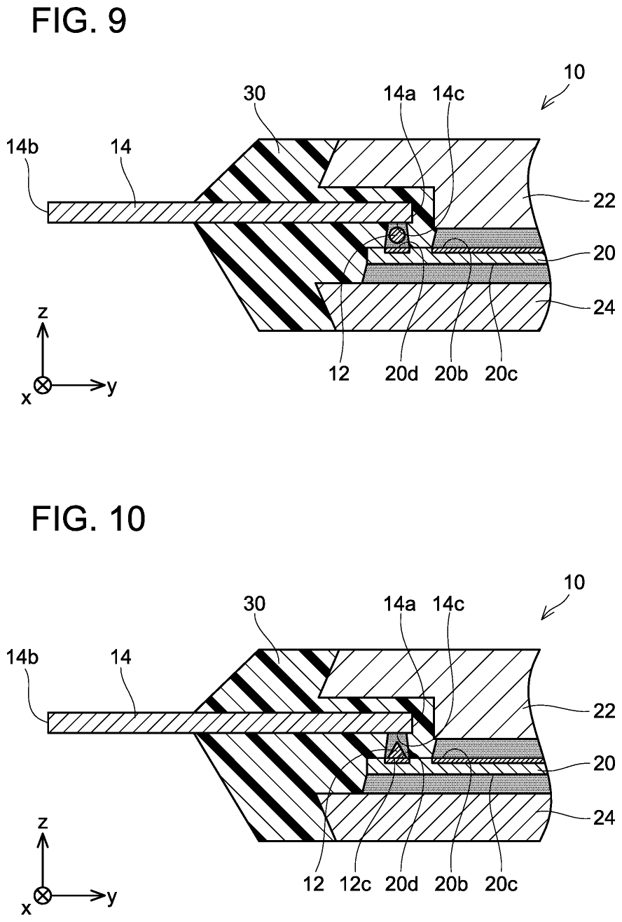

As shown in FIG. 8, the size (C) of the flat surfaces 14c of the first signal terminals 14 may be larger than the size (B) of the signal pads 20d only in the Y direction. Even with such a configuration, when the first signal terminals 14 are positionally displaced in the Y direction, the flat surfaces 14c of the first signal terminals 14 can remain opposed to the entireties or substantially entireties of the signal pads 20d. Since the solder bonding the flat surfaces 14c and the signal pads 20d is retained on the signal pads 20d regardless of the positions of the first signal terminals 14, the solder is suppressed from contacting the unintended portions of the first semiconductor element 20. Further, in this case, the size (B) of the signal pads 20d may be designed to be smaller in the X direction and larger in the Y direction with an area of each signal pad 20d maintained constant. This allows increase in a size of the first main electrode 20b of the first semiconductor element 20. Further, as shown in FIGS. 9, 10, and 11, the recessed portions 14d may not be provided on the first signal terminals 14. As such, each of the flat surfaces 14c of the first signal terminals 14 may extend from the one end portion 14a to the other end portion 14b of the first signal terminal 14.

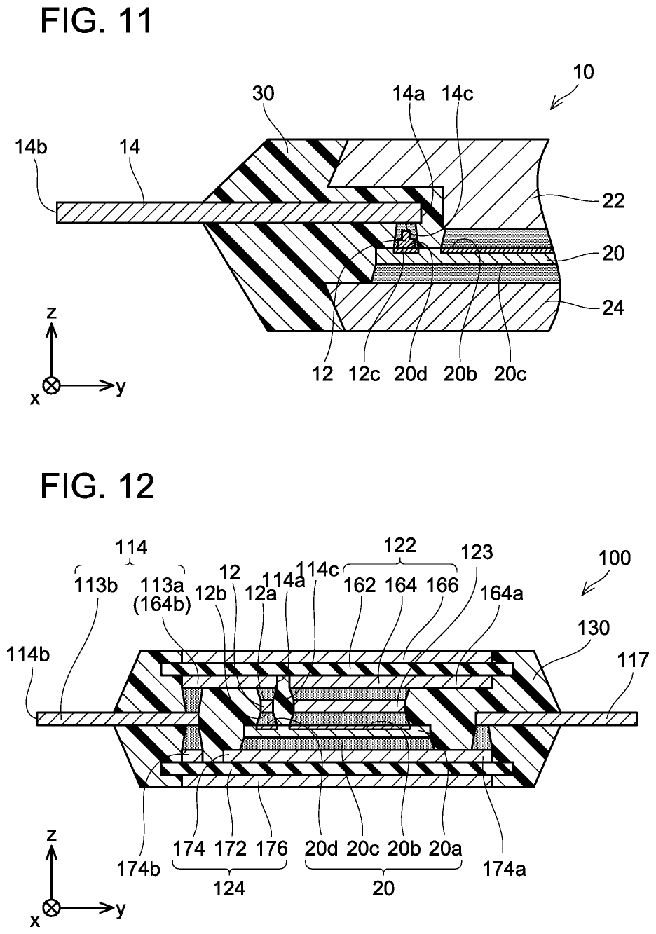

The shape of the signal terminal spacers 12 is also not particularly limited. As shown in FIG. 9, the signal terminal spacers 12 may have a spherical shape. Further, each of the signal terminal spacers 12 may include a bottom surface 12c opposed to its corresponding signal pad 20d. In this case, as shown in FIG. 10, each signal terminal spacer 12 may have a shape in which its cross sectional area continuously decreases toward the flat surface 14c. The signal terminal spacers 12 may have a truncated cone shape, although this is merely an example, and a shape of the bottom surfaces 12c is not particularly limited. Alternatively, as shown in FIG. 11, each signal terminal spacer 12 may have a shape in which its cross sectional area decreases stepwise toward the flat surface 14c. The signal terminal spacers 12 may have a step shape, although this is merely an example, and the shape of the bottom surfaces 12c is not particularly limited. Further, positions of the signal terminal spacers 12 relative to the solder are not particularly limited, either. As shown in FIGS. 9 to 11, the signal terminal spacers 12 may be located within the solder.

### Second Embodiment

A semiconductor device 100 of a second embodiment will be described with reference to FIG. 12. As compared to the semiconductor device 10 of the first embodiment, the semiconductor device 100 of the present second embodiment includes an upper heat dissipating plate 122 and a lower heat dissipating plate 124 with modified structures. Accordingly, especially signal terminals 114 have a modified structure. In these regards, the semiconductor device 100 of the second embodiment differs from the above-described semiconductor device 10 of the first embodiment. The semiconductor device 100 of the present embodiment includes a semiconductor element 20, the upper heat dissipating plate 122, the lower heat dissipating plate 124, a conductor spacer 123, a plurality of external connection terminals 114, 117, a plurality of signal terminal spacers 12, and an encapsulant 130. Configurations of the semiconductor element 20 and the signal terminal spacers 12 are similar to those of the first embodiment, thus descriptions thereof will be omitted. Further, the number of semiconductor elements included in the semiconductor device 100 is not particularly limited.

The semiconductor element 20 is encapsulated within the encapsulant 130. The encapsulant 130 is constituted mainly of a material having insulation property. The encapsulant 130 may be constituted mainly of a thermosetting resin such as epoxy resin, although this is merely an example.

The plurality of external connection terminals 114, 117 protrudes outward from the encapsulant 130. Each of the external connection terminals 114, 117 is electrically connected to the semiconductor element 20 inside the encapsulant 130. The plurality of external connection terminals 114, 117 is constituted mainly of a conductor material such as copper. The plurality of external connection terminals 114, 117 includes a plurality of signal terminals 114 and a plurality of power terminals 117. The numbers of the signal terminals 114 and the power terminals 117 are not particularly limited.

The upper heat dissipating plate 122 and the lower heat dissipating plate 124 are opposed to each other with the semiconductor element 20 interposed therebetween. The conductor spacer 123 and the plurality of signal terminal spacers 12 are interposed between the upper heat dissipating plate 122 and the semiconductor element 20. The conductor spacer 123 is located above the first main electrode 20b, and the signal terminal spacers 12 are located above the signal pads 20d. Here, the conductor spacer 123 is not necessarily required, however, it can secure a space where the signal terminals 114 are bonded to the signal pads 20d. The conductor spacer 123 is constituted mainly of a conductor material such as copper.

The upper heat dissipating plate 122 includes a first insulator substrate 162, a first inner conductor layer 164 provided on one side of the first insulator substrate 162, and a first outer conductor layer 166 provided on another side of the first insulator substrate 162. Similarly, the lower heat dissipating plate 124 includes a second insulator substrate 172, a second inner conductor layer 174 provided on one side of the second insulator substrate 172, and a second outer conductor layer 176 provided on another side of the second insulator substrate 172.

The first inner conductor layer 164 includes a plurality of partial regions 164a, 164b. The plurality of partial regions 164a, 164b includes a first partial region 164a and second partial regions 164b. The first partial region 164a and the second partial regions 164b are independent (separated) from each other on the first insulator substrate 162. The first partial region 164a and the second partial regions 164b are electrically connected to the semiconductor element 20 within the encapsulant 130. Similarly, the second inner conductor layer 174 includes a plurality of partial regions 174a, 174b. The plurality of partial regions 174a, 174b includes a third partial region 174a and fourth partial regions 174b. The third partial region 174a and the fourth partial regions 174b are independent (separated) from each other on the second insulator substrate 172. The third partial region 174a is electrically connected to the semiconductor element 20 within the encapsulant 130. The fourth partial regions 174b are connected to second signal terminal portions 113b to be described later, and physically support the second signal terminal portions 113b.

The first partial region 164a is opposed to the first main electrode 20b of the semiconductor element 20, and the third partial region 174a is opposed to the second main electrode 20c of the semiconductor element 20. Further, the first partial region 164a is electrically connected to the first main electrode 20b via the conductor spacer 123. Similarly, the third partial region 174a is electrically connected to the second main electrode 20c. On the other hand, the second partial regions 164b are opposed to the signal pads 20d of the semiconductor element 20. The second partial regions 164b are electrically connected to the signal pads 20d via the signal terminal spacers 12. Connections of the respective constituent members are realized by bonding with a bonding material having conductivity such as solder. However, these connections are not limited to be realized by soldering, and may be realized by other aspects.

The second outer conductor layer 176 is exposed at one surface of the encapsulant 130, and the first outer conductor layer 166 is exposed at another surface of the encapsulant 130. Due to this, the first outer conductor layer 166 and the second outer conductor layer 176 function as heat dissipating plates that dissipate heat generated in the semiconductor element 20.

The upper heat dissipating plate 122 and the lower heat dissipating plate 124 of the present embodiment are DBC (Direct Bonded Copper) substrates, although this is merely an example. The insulator substrates 162, 172 are constituted mainly of a ceramic material such as aluminum oxide, silicon nitride, and aluminum nitride. Further, the inner conductor layers 164, 174 and the outer conductor layers 166, 176 are constituted mainly of copper. However, the heat dissipating plates 122, 124 are not limited to DBC substrates, and may, for example, be DBA (Direct Bonded Aluminum) substrates or AMC (Active Metal Brazed Copper) substrates. Alternatively, the insulator substrates 162, 172 may have structures different from the DBC substrates, the DBA substrates, or the AMC substrates. Configurations of the heat dissipating plates 122, 124 are not particularly limited. The heat dissipating plates 122, 124 simply need to include the insulator substrates 162, 172 constituted mainly of an insulative material and the inner conductor layers 164, 174 and the outer conductor layers 166, 176 constituted mainly of conductor such as metal, respectively. Further, how the first insulator substrate 162 and each of the conductor layers 164, 166 of the upper heat dissipating plate 122 are bonded is not particularly limited, and how the insulator substrate 172 and each of the conductor layers 174, 176 of the lower heat dissipating plate 124 are bonded is not particularly limited, either.

Further, the power terminal 117 is connected to the third partial region 174a of the second inner conductor layer 174. A connection between the third partial region 174a and the power terminal 117 is realized by bonding with a bonding material having conductivity such as solder. However, it is not limited to be realized by soldering, and may be realized by other aspects.

Each of the signal terminals 114 extends from one end portion 114a thereof to another end portion 114b thereof located opposite to the one end portion 114a. Each of the signal terminals 114 includes a first signal terminal portion 113a including the one end portion 114a and a second signal terminal portion 113b including the other end portion 114b. The first signal terminal portions 113a are configured using the second partial regions 164b of the upper heat dissipating plate 122. Each second signal terminal portion 113b is configured of an elongated plate-shaped member. The first signal terminal portions 113a extend along the Y direction from above the signal pads 20d to above the second signal terminal portions 113b. The second signal terminal portions 113b extend from above the fourth partial regions 174b within the encapsulant 130 to the outside. Each first signal terminal portion 113a and its corresponding second signal terminal portion 113b are partially opposed to each other, and are electrically connected to each other. The first signal terminal portions 113a and the second signal terminal portions 113b are bonded to each other, using a bonding material having conductivity such as solder. Each fourth partial region 174b is, for example, soldered to its corresponding second signal terminal portion 113b and supports the second signal terminal portion 113b from below. However, the second signal terminal portions 113b and the fourth partial regions 174b may not be soldered to each other, and may be connected to each other by other aspects. Each second signal terminal portions 113b is configured using a conductor member such as copper or other metal.

The first signal terminal portions 113a each include a flat surface 114c on a one end portion 114a side, and this flat surface 114c is opposed to the corresponding signal pad 20d. Further, a size of the flat surfaces 114c is larger than a size of the signal pads 20d in both the X and Y directions. Further, the one end portions 114a including the flat surfaces 114c extend along the Y direction. Each of the signal terminal spacers 12 is located between the flat surface 114c of its corresponding signal terminal 114 and its corresponding signal pad 20d. As such, the flat surfaces 114c of the signal terminals 114 are bonded to the signal pads 20d with the signal terminal spacers 12 interposed therebetween. In this arrangement, the first end surfaces 12a of the signal terminal spacers 12 are opposed to the flat surfaces 114c, and the second end surfaces 12b of the signal terminal spacers 12 are opposed to the signal pads 20d. Due to this, the flat surfaces 114c of the signal terminals 114 are soldered to the first end surfaces 12a of the signal terminal spacers 12, and the second end surfaces 12b of the signal terminal spacers 12 are soldered to the signal pads 20d.

In the semiconductor device 100 of the present embodiment as well, the signal terminals 114 include the flat surfaces 114c opposed to the signal pads 20d. The flat surfaces 114c are larger than the signal pads 20d in at least one direction (X direction and/or Y direction) parallel to the flat surfaces 114c. According to this configuration, even when the signal terminals 114 are positionally displaced in the at least one direction, the flat surfaces 114c of the signal terminals 114 can remain opposed to entireties or substantially entireties of the corresponding signal pads 20d. Since the solder bonding the flat surfaces 114c and the signal pads 20d is retained on the signal pads 20d regardless of the positions of the signal terminals 114, the solder is suppressed from contacting the unintended portions of the semiconductor element 20. Further, since the signal terminal spacers 12 are arranged between the flat surfaces 114c of the signal terminals 114 and the signal pads 20d, a certain distance can be secured between the flat surfaces 114c of the signal terminals 114 and the signal pads 20d.

What is claimed is:

1. A semiconductor device comprising:
a semiconductor element comprising a signal pad; and
a signal terminal comprising a flat surface opposed to the signal pad, the flat surface being bonded to the signal pad with a spacer interposed therebetween,
wherein
the flat surface is larger than the signal pad in at least one direction parallel to the flat surface.

2. The semiconductor device according to claim 1, wherein the signal pad is larger than the spacer in the at least one direction.

3. The semiconductor device according to claim 1, wherein
an end portion of the signal terminal extends along a first direction, the end portion including at least the flat surface, and
the at least one direction comprises the first direction.

4. The semiconductor device according to claim 3, wherein the at least one direction further comprises a second direction perpendicular to the first direction.

5. The semiconductor device according to claim 1, wherein the spacer has a pillar shape including one end surface opposed to the flat surface and another end surface opposed to the signal pad.

6. The semiconductor device according to claim 1, wherein the spacer has a spherical shape.

7. The semiconductor device according to claim 1, wherein the spacer comprises a bottom surface opposed to the signal pad and has a shape in which a cross sectional area of the spacer decreases continuously or stepwise toward the flat surface.

8. The semiconductor device according to claim 1, wherein
the flat surface is bonded to the signal pad via solder, and
the spacer is located within the solder.

9. The semiconductor device according to claim 1, wherein at least a part of the signal terminal is provided on an insulator substrate.
